(19) United States
(12) Patent Application Publication
(10) Pub. No.: US 2026/0223754 A1
(43) Pub. Date: Jul. 30, 2026

(54) WAFER-SCALE INTEGRATION POWER DELIVERY WITH AN ISOTROPIC CONDUCTIVE ADHESIVE

(71) Applicant: Volantis Semiconductor, Inc., Portland, OR (US)

(72) Inventors: Kevin Nan Lam, Pleasanton, CA (US); Tapabrata Ghosh, San Francisco, CA (US)

(73) Assignee: Volantis Semiconductor, Inc., Portland, OR (US)

(21) Appl. No.: 19/461,845

(22) Filed: Jan. 28, 2026

Related U.S. Application Data
(63) Continuation-in-part of application No. 19/387,789, filed on Nov. 13, 2025.
Application No. 19/387,789 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/750,822, filed on Jan. 29, 2025.
(60) Provisional application No. 63/750,817, filed on Jan. 29, 2025.
(60) Provisional application No. 63/720,216, filed on Nov. 14, 2024.
(60) Provisional application No. 63/714,353, filed on Oct. 31, 2024.

(51) Int. Cl. H10W 90/00; H10W 70/60; H10W 72/00; H10W 72/20; H10W 90/10; H10W 90/22; H10W 70/63

(52) U.S. Cl. CPC H10W 90/724; H10W 70/611; H10W 72/01223; H10W 72/01225; H10W 72/225; H10W 72/253; H10W 90/10; H10W 90/22; H10W 70/635

(57) ABSTRACT

A wafer-scale integration (WSI) system is accessed. The WSI system comprises a monolithic wafer. The plurality of functional chips is manufactured on the monolithic wafer. The WSI system comprises a wafer interposer. The plurality of functional chips comprises a plurality of functional chiplets. A front side of the wafer interposer is bonded to the plurality of functional chiplets, and the wafer interposer includes a plurality of through-silicon vias (TSVs). The WSI system includes a plurality of functional chips. At least one power module is coupled, by one or more isotropic conductive adhesives (ICAs), to the WSI system. DC power is sent, by the at least one power module, to the plurality of functional chips. The sending is based on the one or more ICAs. The sending includes one or more voltage conversions.

### RELATED APPLICATIONS

This application claims the benefit of U.S. provisional application “Chiplet-Based Optical Wafer-Scale Network Switch” Ser. No. 63/750,817, filed January 29, 2025, and “Wafer-Scale Integration Power Delivery With An Isotropic Conductive Adhesive” Ser. No. 63/750,822, filed January 29, 2025.

This application is also a continuation-in-part of U.S. patent application “Back Side Power Delivery With An Anisotropic Conductive Film” Ser. No. 19/387,789, filed November 13, 2025, which claims the benefit of U.S. provisional applications “Back Side Wafer-Scale Power Delivery With An Anisotropic Film” Ser. No. 63/720,216, filed November 14, 2024, “Chiplet-Based Optical Wafer-Scale Network Switch” Ser. No. 63/750,817, filed January 29, 2025, and “Wafer-Scale Integration Power Delivery With An Isotropic Conductive Adhesive” Ser. No. 63/750,822, filed January 29, 2025.

The U.S. patent application “Back Side Power Delivery With An Anisotropic Conductive Film” Ser. No. 19/387,789, filed November 13, 2025, is also a continuation-in-part of U.S. patent application “Back Side Power Delivery For Wafer-Scale Integration With An Isometric Grid Compression Plate” Ser. No. 19/056,456, filed February 18, 2025, which claims the benefit of U.S. provisional patent applications “Chiplet-Based Optical Wafer-Scale Network Switch” Ser. No. 63/750,817, filed January 29, 2025, and “Wafer-Scale Integration Power Delivery With An Isotropic Conductive Adhesive” Ser. No. 63/750,822, filed January 29, 2025.

The U.S. patent application “Back Side Power Delivery For Wafer-Scale Integration With An Isometric Grid Compression Plate” Ser. No. 19/056,456, filed February 18, 2025 is also a continuation-in-part of U.S. patent application “Back Side Power Delivery For Wafer-Scale Integration With Solderless Modular Power Substrates” Ser. No. 19/023,647, filed January 16, 2025, which claims the benefit of U.S. provisional patent applications “Cooling for Wafer-Scale Integration With Back Side Power Coupling” Ser. No. 63/714,353, filed October 31, 2024, and “Back Side Wafer-Scale Power Delivery With An Anisotropic Film” Ser No. 63/720,216, filed November 14, 2024.

The U.S. patent application “Back Side Power Delivery For Wafer-Scale Integration With Solderless Modular Power Substrates” Ser. No. 19/023,647, filed January 16, 2025 is also a continuation-in-part of U.S. patent application “Wafer-Scale Integration With A Stiffening Isometric Grid Array” Ser. No. 18/978,188, filed December 12, 2024, which claims the benefit of U.S. provisional patent applications “Cooling for Wafer-Scale Integration With Back Side Power Coupling” Ser. No. 63/714,353, filed October 31, 2024, and “Back Side Wafer-Scale Power Delivery With An Anisotropic Film” Ser. No. 63/720,216, filed November 14, 2024.

The U.S. patent application “Wafer-Scale Integration With A Stiffening Isometric Grid Array” Ser. No. 18/978,188, filed December 12, 2024 is also a continuation-in-part of U.S. patent application “Cold Plate Cooling For Wafer-Scale Integration With Back Side Modular Power Delivery” Ser No. 18/958,107, filed November 25, 2024, which claims the benefit of U.S. provisional patent applications “Cooling for Wafer-Scale Integration With Back Side Power Coupling” Ser. No. 63/714,353, filed October 31, 2024, and “Back Side Wafer-Scale Power Delivery With An Anisotropic Film” Ser No. 63/720,216, filed November 14, 2024.

The U.S. patent application “Cold Plate Cooling For Wafer-Scale Integration With Back Side Modular Power Delivery” Ser No. 18/958,107, filed November 25, 2024, is also a continuation-in-part of U.S. patent application “Back Side Wafer-Scale Integration With Modular Power Delivery” Ser. No. 18/940,944, filed November 8, 2024, which claims the benefit of U.S. provisional patent application “Cooling for Wafer-Scale Integration With Back Side Power Coupling” Ser. No. 63/714,353, filed October 31, 2024.

Each of the foregoing applications is hereby incorporated by reference in its entirety.

### FIELD OF ART

This application relates generally to power delivery and more particularly to wafer-scale integration power delivery with an isotropic conductive adhesive.

### BACKGROUND

Energy is a critical component for any successful society. Early societies used fire as an important energy source. Fire heated abodes, cooked foods, and later, was used to manufacture such important devices as tools, canoes, building materials, and so on. When controlled electrical energy was developed, vast new opportunities for societal improvement arose. Electric lighting, electric heat pumps, electric vehicles, and electric microwave ovens, to name but a very few uses of electrical energy, became available in modern societies due to dependable electricity generation and transmission. However, the generation of electrical energy does not come without a cost. Various types of electricity generation are available, but each comes with different tradeoffs. For example, solar energy is renewable, but costly and inefficient to produce. Fossil fuels are plentiful and relatively inexpensive, but they create pollutants in the process of electricity generation. Nuclear power is “clean” with regard to airborne pollutants, but “dirty” with regard to nuclear waste. However electrical power is produced, it must then be delivered to its end purpose. The delivery can be through regional or even national powerlines and grids to local substations to telephone pole powerlines supplying individual homes, businesses, and industrial complexes. Once available at an end location, it must further be delivered to its target consumption point within the end location.

Of the various types of consumption points that exist today, one of the most prevalent types is an electronic device. Electronic devices can range from personal wearable devices to huge computer datacenters, and everything in between. Common to such a range of devices is the use of integrated circuits (ICs). Different types of ICs, or “chips,” consume different amounts of power. Further, the power consumption of each chip within a system is critical to the success or failure of the system. At one end of the design spectrum, chips that are used in personal electronic devices such as smartwatches, smartphones, tablets, laptop computers, and so on must be designed to balance energy efficiency with processing power. If a smartwatch or smartphone, for example, needed to be recharged every hour, this would not be practical. While a similar situation arises for a laptop computer, the laptop computer also must possess sufficient processing power to be useful. A laptop computer that could operate all day, but barely had enough processing power to execute needed applications, would similarly be purposeless. At the other end of the design spectrum, chips are used in powerful computing systems such as servers, supercomputers, and AI engines, to name only a few. Those chips are designed to be fast, and, as a result, can consume prodigious amounts of power. Furthermore, the result of the power consumption by the chips is the generation of copious heat. Chip design must be carefully executed so that the heat generated by the chips does not damage the chips or other elements nearby the chips. Power delivery to chips, and the power dissipation associated with that power delivery, is an increasingly important aspect of electrical energy usage.

### SUMMARY

Computer users routinely demand faster computers and better applications. Whether the computers are vast server farms or handheld smartphones, users always want systems and devices that are faster and more capable than prior generations of similar devices. Thus, circuit designers have designed and fabricated integrated circuits with ever-increasing processing performance, expanded data processing options, and “product differentiating” features. Differentiating features now typically include larger touchscreens, higher resolution cameras, spatial audio, biometric sensing, and “cute” applications, among many other enhancements. That said, increasing chip processing speeds and capabilities force the addition of complex and often large circuitry to the chips. To add new circuitry into chips, designers employ two main options: increase the chip dimensions by making the chip larger or increase circuit density by reducing feature sizes. Ideally, the chip would be the size of an entire wafer, and the feature sizes would include greatly reduced wire widths and separation, smaller transistor sizes, minimum contact sizes, and reductions of all other dimensions related to circuity.

Disclosed techniques enable wafer-scale integration power delivery with an isotropic conductive adhesive. A wafer-scale integration (WSI) system is accessed. The WSI system includes a plurality of functional chips. The functional chips can include processor chips, accelerator chips, memory chips, and so on. The WSI can include a plurality of through-silicon vias (TSVs). At least one power module is coupled, by one or more isotropic conductive adhesives (ICAs), to the WSI system. DC power is sent, by the at least one power module, to the plurality of functional chips. The DC power can be provided by one or more DC-to-DC converters. The DC power can include at least DC voltage. The sending is based on the one or more ICAs. The sending includes one or more voltage conversions.

A method for power delivery is disclosed comprising: accessing a wafer-scale integration (WSI) system, wherein the WSI system includes a plurality of functional chips; coupling, using one or more isotropic conductive adhesives (ICAs), to the WSI system, at least one power module; and sending DC power, by the at least one power module, to the plurality of functional chips, wherein the sending is based on the one or more ICAs, and wherein the sending includes one or more voltage conversions. In embodiments, the WSI system comprises a wafer interposer. In embodiments, the plurality of functional chips comprises a plurality of functional chiplets. In embodiments, a front side of the wafer interposer is bonded to the plurality of functional chiplets. Some embodiments comprise coupling, using one or more ICAs, to a back side of the wafer interposer, a plurality of modular power substrates (MPSs). In embodiments, each ICA in the one or more ICAs enables each MPS in the plurality of MPSs to be further coupled, based on a TSV in the plurality of TSVs, to one or more functional chiplets within the plurality of functional chiplets.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for wafer-scale integration power delivery with an isotropic conductive adhesive.

FIG. 2 is a flow diagram for isotropic conductive adhesive usage.

FIG. 3 is an illustration of an isotropic conductive adhesive.

FIG. 4 illustrates a cross section for power delivery with an isotropic conductive adhesive and a monolithic WSI system.

FIG. 5 illustrates a cross section for back side wafer-scale power delivery with an isotropic conductive adhesive and a wafer interposer.

FIG. 6 is an infographic for wafer-scale integration power delivery with an isotropic conductive adhesive.

FIG. 7 is an infographic of an apparatus for back side wafer-scale power delivery using a wafer interposer.

### DETAILED DESCRIPTION

Techniques using wafer-scale integration power delivery with an isotropic conductive adhesive are disclosed. Processor performance improvements have skyrocketed in recent years. The improvements directly correlate with the development of new processor technologies and architectures. These improvements aim to meet the ever-increasing processing demands of applications for processors, accelerators, and so on. This demand is placing immense pressure on designers to develop next generation chips that can provide power to computers, servers, cloud servers, large language model (LLM) engines, etc. Tremendously increased numbers of transistors have been added to chips, and architectures such as systems-on-chip (SOCs) have been expanded. SOCs can include circuitry which can include processors, memories, input/output (I/O) circuits, and other elements. These SOCs can be dimensionally large, boasting tens of billions of transistors. At the same time, the feature sizes of the transistors, interconnect, etc. used for these large chips continue to shrink. Keeping chip sizes roughly the same while increasing transistor count is generally good news, but the new technologies that feature smaller transistors also impose new challenges for designers. For example, as a transistor shrinks, leakage currents can increase, resulting in substantial power consumption by the chip. This effect, in combination with the active power required for billions of transistors, can drive extremely high-power densities for processors and other computing elements. Further, the wafers on which these large chips are fabricated are delicate. The wafers can crack and fracture if the wafers are not properly handled and supported.

The vast use of artificial intelligence (AI) applications, such as large neural networks, transformers, and so on, can require hundreds or even thousands of processing elements to handle the perhaps trillions of computations required by the AI applications. These processing elements can include processor cores, multiprocessor cores, matrix computation accelerators, SOCs, and so on. While multiple cores such as processor cores and memory cores can be included on the same chip, many chips are required for executing these computational resource-intensive applications. The processing chips can be in communication with other processing chips, some of which are located locally while others are located remotely. The processing chips are typically coupled via cards, racks, and data centers. The chips, when taken together, introduce significant design challenges such as the provision of power to the chips, the cooling of all these chips, etc. For example, cooling has become a complex challenge, especially when thermal design power (TDP), a measurement of the maximum power consumed by a chip under normal operating conditions, continues to increase.

A wafer-scale integration (WSI) system is accessed, where the WSI system includes a plurality of functional chips. The functional chips can include processors, memory, switching elements, and so on. The WSI system can include a monolithic wafer. The plurality of functional chips is manufactured on the monolithic wafer. The WSI system can include a wafer interposer. The plurality of functional chips can comprise a plurality of functional chiplets. A front side of the wafer interposer can be bonded to the plurality of functional chiplets. One or more isotropic conductive adhesives (ICAs) couple at least one power module to the WSI system. The power module can include a modular power substrate. DC power is sent, by the at least one power module, to the plurality of functional chips. The sending can be accomplished using through-silicon vias (TSVs), interconnect, and the like. The TSVs and the interconnect are manufactured through and on the monolithic wafer or wafer interposer, respectively. The sending is based on the one or more ICAs, wherein the sending includes one or more voltage conversions. The ICAs can include micro-silver flakes, polymer spheres, etc. The voltage conversions can be accomplished using DC-to-DC converters.

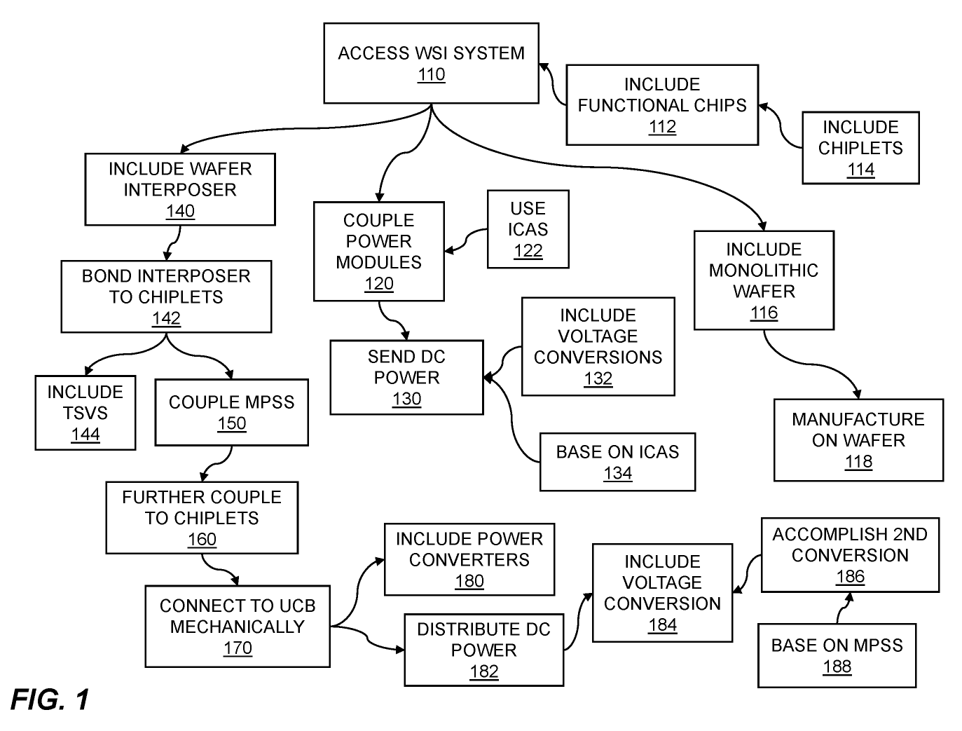

FIG. 1 is a flow diagram for wafer-scale integration power delivery with an isotropic conductive adhesive. Wafer-scale integration has been a long-sought goal of integrated circuit design. With wafer-scale integration, an entire, monolithic wafer such as a silicon wafer could be used to fabricate one large integrated circuit. However, since physical defects in the silicon wafer are distributed across the wafer, portions of circuitry which were fabricated over the defects would likely not function properly. In addition, errors that occur when fabricating the many layers that form the integrated circuit further create portions of the integrated circuit that would likely not function. Instead, a plurality of functional chips can be manufactured on the monolithic wafer. The operational functional chips can be used, and the nonoperational functional chips can be excluded. Further, individual integrated chips can be attached or bonded to the WSI system. By doing so, wafer-scale integration can be achieved, while allowing chips from different manufacturing processes to be included. In such a case, the monolithic wafer can be used as an interposer to couple the integrated circuits.

The flow 100 includes accessing 110 a wafer-scale integration (WSI) system. The WSI system can be based on a wafer. In embodiments, the WSI system comprises a monolithic wafer, wherein a plurality of functional chips is manufactured on the monolithic wafer. In other embodiments, the WSI system comprises a wafer interposer, wherein the plurality of functional chips comprises a plurality of functional chiplets, wherein a front side of the wafer interposer is bonded to the plurality of functional chiplets, and wherein the wafer

interposer includes a plurality of through-silicon vias (TSVs). The wafer can be a 300 mm wafer, a 200 mm wafer, or a wafer of another size. The wafer can comprise silicon or another suitable material. In a usage example, another suitable material can include glass. The wafer can include any amount of front-end-of-line (FEOL) processing and/or back-end-of line (BEOL) processing. The processing can be based on Complementary Metal-Oxide-Semiconductor (CMOS), Silicon on Insulator (SOI), or another process.

In the flow 100, the WSI system includes a plurality of functional chips 112. The WSI system can have a front side and a back side onto which elements such as the functional circuit elements can be manufactured, attached, or bonded. The functional chips can include general-purpose chips such as processor chips, multiprocessor chips, graphics processor chips, application-specific integrated circuits (ASICs), memory chips, and so on. The plurality of functional chips includes one or more artificial intelligence (AI) accelerators. The WSI system may include a plurality of through-silicon vias (TSVs). A TSV can include an electrical connection that completely passes through a wafer such as a silicon wafer, a glass wafer, a die, and so on. The plurality of TSVs can be oriented vertically in order to enable connections between the front side of the wafer and the back side of the wafer. Chips such as the functional chips can be positioned such that connections to the chips align with the TSVs. In some examples, a wafer can be ground to enable TSV processing with repeatable shapes and parasitic characteristics. The function chips can include functional chiplets 114 that are relatively small and have well-defined, narrow functionality.

In exemplary implementations, the WSI system comprises a monolithic wafer 116, wherein the plurality of functional chips is manufactured on the monolithic wafer 118. The monolithic wafer can include a plurality of functional cores that are fabricated on the wafer. The functional cores can include one or more processors, AI accelerators, ASICs, peripheral interfaces, and so on. The functional cores can include memory. Other memory elements, such as SRAM, can be included in the monolithic wafer. The memory elements can also be fabricated on the wafer. Interconnect can be included on the monolithic wafer to couple any number of the functional cores, memory elements, and so on. The interconnect can comprise any number of metal layers on the wafer.

The flow 100 includes coupling power modules 120. The power modules can be coupled to the WSI system by one or more isotropic conductive adhesives (ICAs) 122. A

power module can include a modular power substrate (MPS), discussed below. A variety of ICAs can be used to accomplish the coupling. In embodiments, the ICA comprises micro-silver flakes. The micro-silver flakes can be suspended in an adhesive such as an epoxy, cyanoacrylate, and so on. The micro-silver flakes are conductive and enable power transfer, control, and other signals to be provided to and received from the power module. In embodiments, the ICA comprises an epoxy-based isotropic conductive adhesive. In embodiments, the ICA comprises polymer spheres. The polymer spheres can conform to irregular surfaces. The polymer spheres can conform to a TSV, a contact, and the like. The polymer spheres can be used to accomplish bonding rather than using an adhesive film.

The flow 100 includes sending DC power 130. The DC power can be sent to the plurality of functional chips by the at least one power module. The sending DC power can be accomplished via one or more TSVs, by interconnect manufactured on the monolithic wafer, and so on. The sending power can be controlled by one or more control circuits (described below). The sending can include one or more voltage conversions 132. In a usage example, the sending DC power is accomplished using a DC power connector and a plurality of rigid-flex strips. The DC power can be obtained using one or more DC-to-DC converters. The DC-to-DC power converters can convert DC power from a high voltage range to a low voltage range (e.g., from a data center distribution voltage to an integrated circuit usage voltage). The sending can be based on the one or more ICAs 134. The ICAs can include a variety of materials, configurations, and so on. A range of techniques, processes, and the like can be used to apply the ICAs.

The flow 100 includes including wafer interposer 140 in the WSI system. In the flow 100, a front side of the wafer interposer is bonded to the plurality of functional chiplets 142. The bonding can be accomplished using one or more ICAs. The bonding can be accomplished such that the functional chiplets align with contacts, pads, etc. on the front side of the wafer interposer. The wafer interposer can include a plurality of through-silicon vias (TSVs) 144. In a usage example, the functional chiplets are bonded to the wafer interposer at the TSVs.

The flow 100 includes coupling a plurality of modular power substrates (MPSs) 150 to the back side of the wafer interposer, using one or more ICAs. The power modules described above can include one or more MPSs. The MPSs can be modular. The modularity of the MPSs can allow for movement between a UCB (described below) and the WSI. Movement, such as a linear displacement, can occur due to differences in coefficients of

thermal expansion (CTE). The MPSs can be sized to correspond to the size of one or more of the functional chips. In the flow 100, each ICA in the one or more ICAs enables each MPS in the plurality of MPSs to be further coupled to one or more functional chiplets within the plurality of functional chiplets 160. The coupling can be based on the plurality of TSVs and the ICAs. The functional chiplets can include processor chiplets, multiprocessor chiplets, switching chiplets, memory chiplets, etc.

The flow 100 includes connecting mechanically 170 the plurality of MPSs to a unified control board (UCB), wherein the UCB includes a plurality of DC-to-DC power converters 180. The connecting mechanically can be accomplished using plug-and-socket connectors, terminals, pins, clips, cables, and so on. The connecting mechanically can be based on a high-power socket, a high voltage socket, etc. The UCB can include one or more control circuits. The control circuits can include digital control circuits such as a processor, a multiprocessor, a microcontroller, and so on. The control circuits can control the plurality of MPSs. The UCB includes a plurality of DC-to-DC power converters. The DC-to-DC power converters can convert DC power from a high voltage range to a low voltage range (e.g., buck conversion). In a usage example, the DC-to-DC converters can convert DC power from a high voltage range, such as 48 volts to 54 volts, to a lower voltage range, such as 12 volts to 13.5 volts. The higher voltage range can be a voltage range normally supplied to racks within a data center.

The MPSs can include power elements such as DC-to-DC converters, connectors such as high-power connectors, further connectors such as rigid-flex strips, and so on. The DC-to-DC converters associated with the MPSs can provide power to functional chips. Each DC-to-DC converter in the plurality of DC-to-DC power converters is coupled to one or more functional chips in the plurality of functional chips. The MPSs can receive DC power, where the DC power can be sent by a control board such as a unified control board (discussed below). The DC power that is received by the plurality of MPSs can be transferred to the plurality of functional chips. The transferring can be based on a voltage conversion such as a DC voltage conversion. Each MPS within the plurality of MPSs can be based on a form factor mirroring one or more corresponding functional chips within the plurality of functional chips on the front side of the WSI system. The form factor can be based on one or more parameters

associated with the one or more corresponding functional chips. In a usage example, the form factor can be based on a coefficient of thermal expansion (CTE).

In the flow 100, the sending includes distributing DC power 182. The DC power distribution can be enabled by the UCB to power the plurality of functional chiplets. The DC power distribution can include a first voltage conversion. The DC power can be distributed to the functional chiplets via the TSVs, interconnect, etc. Recall that the plurality of functional chiplets is bonded to the front side of the WSI. The distributing DC power can be further based on converting one or more DC voltages 184. In a usage example, a first voltage conversion can include converting a voltage in a range, such as 48 volts to 54 volts, to a voltage in a lower range, such as 12 volts to 13.5 volts. The first voltage conversion can be controlled by the control circuits included on the UCB. The transferring DC power can include additional DC power conversions. In embodiments, a second voltage conversion 186 can be accomplished by the plurality of MPSs 188. The second voltage conversion can convert a voltage to a voltage below a threshold. The second voltage conversion can change the voltage that the functional chips receive to an appropriate operating level, such as less than 1 volt. In embodiments, the UCB includes a plurality of DC-to-DC power converters. In embodiments, the sending includes distributing DC power, by the UCB, to the plurality of functional chiplets. In embodiments, the distributing includes a first voltage conversion within the one or more voltage conversions. In embodiments, the distributing is based on the plurality of MPSs.

The WSI system can be brought in contact with a cold plate. The cold plate contacts the plurality of functional chips bonded to the front side of the WSI system. The cold plate can be used to remove at least a portion of the heat generated by the functional chips while the chips are operating. The mounting the WSI system to the cold plate can be based on one or more spring-loaded fasteners. The cold plate can hold the WSI system, where the holding can apply pressure on the WSI system from the top and the bottom, stiffening the WSI system and maintaining coplanarity. The stiffening can be based on an isometric grid array (IGA) between the WSI system and the plurality of MPSs. The IGA can be particularly critical because the WSI system can be thin. The WSI system, especially when ground or polished to accommodate TSVs, can be fragile. The IGA can thus provide support for the WSI system by enhancing stability, increasing stiffness, reducing the chance of cracking, enabling better electrical

connections across the WSI system, etc. Thus, the IGA maintains a coplanarity of each MPS in the plurality of MPSs.

The cold plate can comprise an inlet plate, a jet-plate, and a fin-plate. The inlet plate can receive a liquid such as a liquid coolant. An inlet nozzle within the inlet plate can be located orthogonally to a heat extraction plane within the fin-plate. The jet-plate can create a spray which can be sprayed onto the fin-plate based on holes in the jet-plate. The holes in the jet-plate can include holes of substantially similar sizes or different sizes. The holes can concentrate a spray onto a region of the fin-plate covering the functional chips. In a usage example, holes toward the center of the jet-plate can be smaller than the holes toward the outer edges of the jet-plate to account for liquid pressure differences across the jet-plate. The fin-plate can include a plurality of internal fins onto which the jet-plate sprays a liquid coolant. The fins can increase the surface area of the fin-plate, thereby enhancing removal of heat from the functional chips to which the fin-plate is attached.

The cold plate provides liquid cooling for the plurality of functional chips. The liquid can include a coolant, where the coolant can be distilled water or another liquid. The coolant can be mixed with additives such as glycol. The attaching the cold plate can include a thermal interface material (TIM). The TIM can conduct heat between surfaces, thus enabling more efficient cooling solutions. The TIM can comprise thermal tape, grease, gel, adhesive, phase change materials (PCMs), metal TIMs, pyrolytic graphite, and so on. In a usage example, the TIM can include an uncured TIM. The uncured TIM can remain flexible or viscous, thereby enabling the cold plate and the functional chips to expand by different lateral displacements based on different coefficients of thermal expansion.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

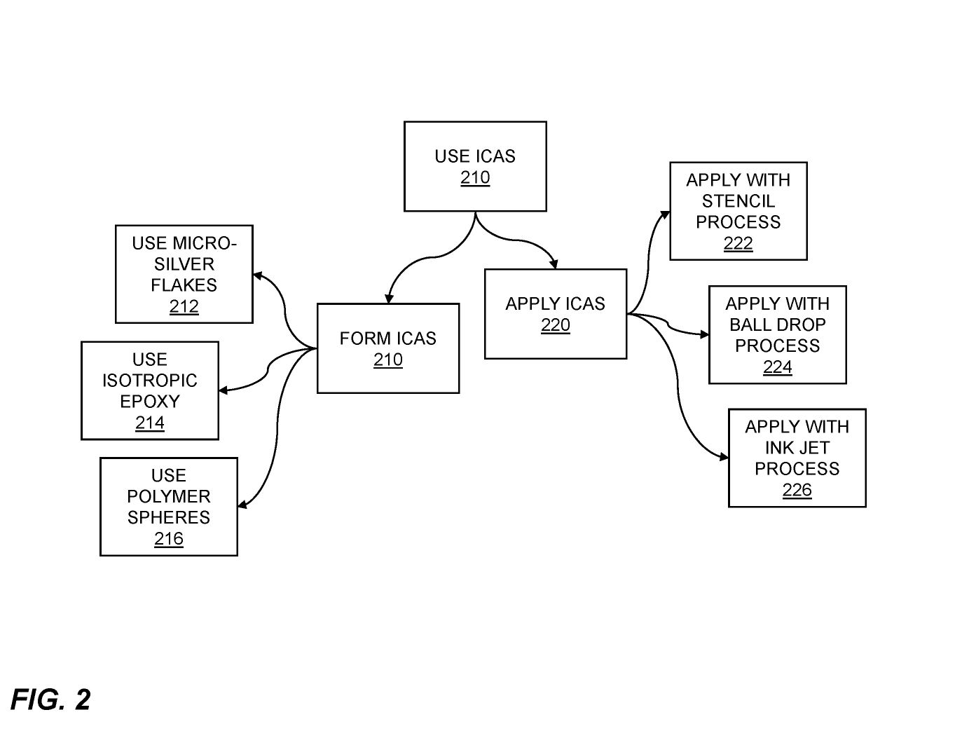

FIG. 2 is a flow diagram for isotropic conductive adhesive usage. Isotropic conductive adhesives can enable wafer-scale integration power delivery. A wafer-scale integration (WSI) system is accessed. The WSI system includes a plurality of functional chips. The functional chips can include processor chips, accelerator chips, memory chips, and so on. The WSI can include a plurality of through-silicon vias (TSVs). At least one power module is

coupled, by one or more isotropic conductive adhesives (ICAs), to the WSI system. DC power is sent, by the at least one power module, to the plurality of functional chips.

The flow 200 includes using isotropic conductive adhesives (ICAs) 210. The ICAs have dual properties of electrical conduction and material adhesion. The electrical conduction can be isotropic, that is, invariant with respect to direction. The material adhesion can provide mechanical stability between two objects, for example, between a wafer interposer and a power module. The resultant conduction and stability can establish a coupling within a WSI system. A variety of ICA types can be used to accomplish the coupling. In embodiments, the ICA comprises micro-silver flakes 212. The micro-silver flakes can be suspended in an adhesive such as an epoxy, cyanoacrylate, and so on. The micro-silver flakes are conductive and enable power transfer, control signal transfer, data signal transfer, and so on to be provided to and received from a power module. In embodiments, the ICA comprises an epoxy-based isotropic conductive adhesive 214. The epoxy-based isotropic conductive adhesive can include the micro-silver flakes described above or another suitable conductive element. In embodiments, the ICA comprises polymer spheres 216. The polymer spheres can be conductive and can conform to irregular surfaces. The polymer spheres can conform to a TSV, a contact, and the like. The micro-silver flakes, the epoxy-based isotropic conductive adhesive, and/or the polymer spheres can be used to accomplish bonding rather than using an adhesive film.

The flow 200 includes applying the ICAs 220. A range of techniques, processes, and the like can be used to apply the ICAs. The ICAs can be applied with a stencil printing process 222. The ICAs can be applied to the wafer through a stencil. The ICAs can be applied with a ball drop process 224. As the name suggests, the ball drop process drops balls of the ICA onto a surface. The ICA balls can be dropped through a stencil. The ICA can be applied with an ink jet deposition process 226. The ink jet process can print the ICA onto the WSI system. The ICAs can be used to couple, both electrically and mechanically, other suitable elements of the WSI system as well.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

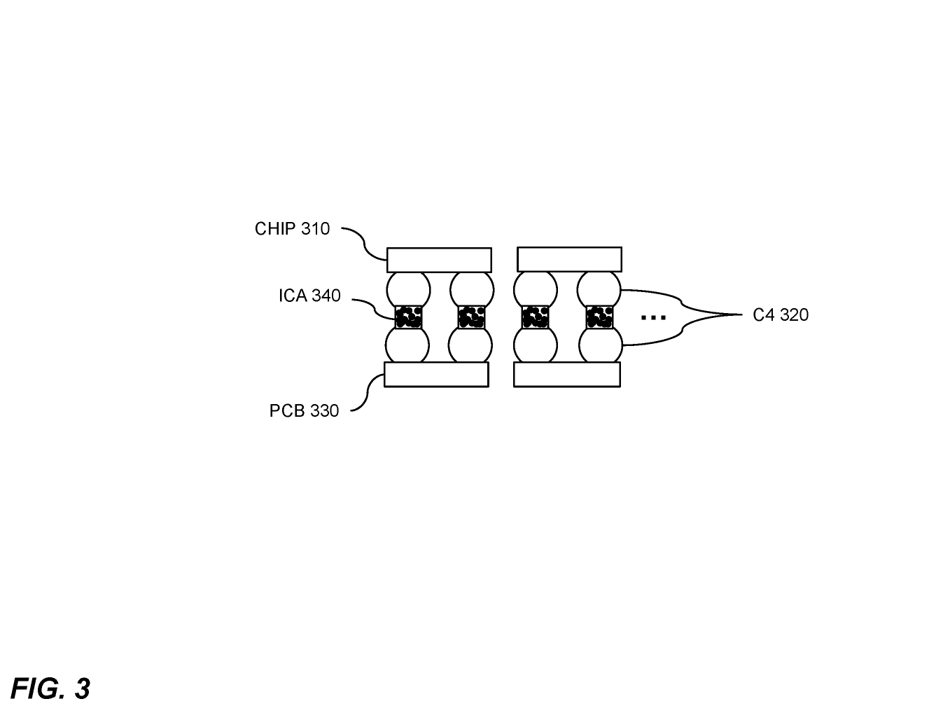

FIG. 3 is an illustration of an isotropic conductive adhesive. An isotropic conductive adhesive can enable wafer-scale integration power delivery. A wafer-scale integration (WSI) system is accessed. The WSI system includes a plurality of functional chips. The functional chips can include processor chips, accelerator chips, memory chips, and so on. The WSI can include a plurality of through-silicon vias (TSVs). At least one power module is coupled, by one or more isotropic conductive adhesives (ICAs), to the WSI system. DC power is sent, by the at least one power module, to the plurality of functional chips.

Discussed previously and throughout, one or more isotropic conductive adhesives (ICAs) are used to couple at least one power module to a wafer-scale integration (WSI) system. The isotropic conductive adhesives accomplish wafer-scale integration power delivery to a plurality of functional chips. The illustration 300 shows a chip 310. The chip can include a processor chip, a multiprocessor chip, an AI accelerator chip, a switching chiplet, and so on. The chip can include a memory chip. Contact to the chip is accomplished using micro-bumps, controlled collapse chip connections (C4s), and so on. Examples of C4 connections are shown 320. The chips can be bonded to a printed circuit board (PCB) 330. The printed circuit board can include an interposer, a wafer-scale integration system, a unified control board (UCB), and the like. The printed circuit board can include a plurality of contacts. The contacts on the PCB can correspond to contacts associated with one or more chips. The contacts on the PCB can include C4 connections. One or more isotropic conductive adhesives 340 can be used to couple one or more chips to the PCB. The ICAs can include micro-silver flakes, polymer spheres, and so on. The one or more ICAs can be applied using a variety of techniques including a stencil printing process, a ball drop process, an ink jet deposition process, etc.

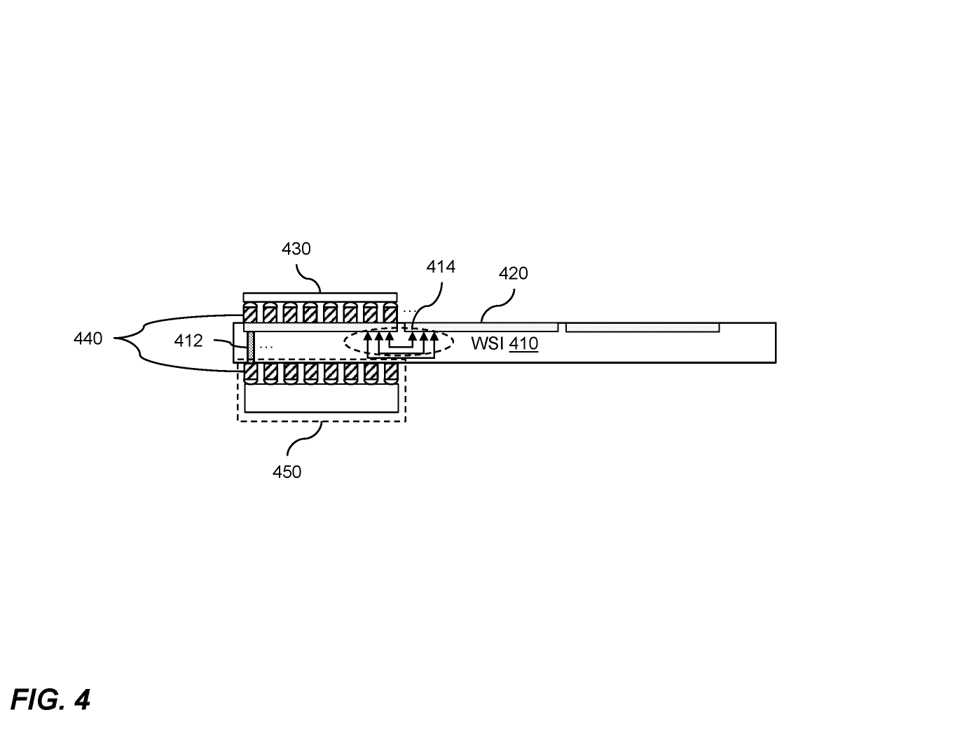

FIG. 4 illustrates a cross-section for power delivery with an isotropic conductive adhesive and a monolithic WSI system. Power delivery from at least one power module to one or more functional chips is accomplished using a wafer-scale integration system (WSI), where the wafer-scale integration system comprises a monolithic wafer. The at least one power module is coupled to the monolithic wafer by one or more isotropic conductive adhesives (ICAs). The functional chips can be manufactured on the monolithic wafer, bonded to a front side of the monolithic wafer, and so on. The at least one power module can be coupled to a back side of the monolithic wafer. Interconnection between the at least one power module and the functional chips can be accomplished using through-silicon vias (TSVs), wiring layers fabricated

on the monolithic wafer, waveguides, and so on. Power delivery to the functional chips is enabled by wafer-scale integration power delivery with an isotropic conductive adhesive. A wafer-scale integration (WSI) system is accessed. The WSI system includes a plurality of functional chips. The functional chips can include processor chips, accelerator chips, memory chips, and so on. The WSI can include a plurality of through-silicon vias (TSVs). At least one power module is coupled, by one or more isotropic conductive adhesives (ICAs), to the WSI system. DC power is sent, by the at least one power module, to the plurality of functional chips.

The illustration 400 shows a cross section for power delivery with an isotropic conduction adhesive. The illustration 400 includes a wafer-scale integration (WSI) system 410. The WSI system includes a plurality of functional chips. The functional chips can be manufactured on the monolithic wafer, bonded to the monolithic wafer, and so on. The WSI system provides interconnect. The interconnect can include through-silicon vias (TSVs) such as TSV 412. The TSVs can provide a conduction path between a front side of the WSI system and a back side of the WSI system. The WSI system includes one or more layers of interconnect 414, as indicated by the dotted line oval. The interconnect can provide paths between the functional chips, such as between functional chip 420, associated with the WSI system, and another chip. For the functional chips that are bonded to the WSI system, such as functional chip 430, the bonding can be accomplished using one or more isotropic conductive adhesives (ICAs) 440. The ICAs can include micro-silver flakes, polymer spheres, and so on. The ICAs can be applied to TSVs, contacts, etc. associated with the WSI system using one or more of a stencil printing process, a ball drop process, an ink jet deposition process, and the like. Recall that at least one power module, such as power module 450, is coupled to the WSI system. The power modules can include modular power substrates. This coupling can also be accomplished by one or more isotropic conductive adhesives.

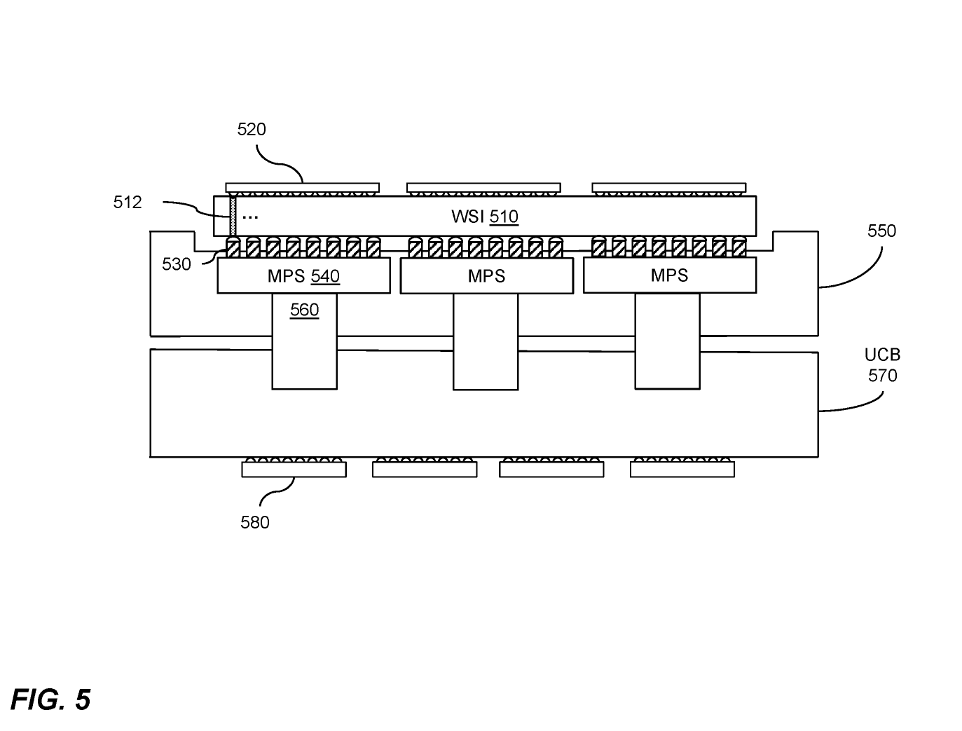

FIG. 5 illustrates a cross section for back side wafer-scale power delivery with an isotropic conductive adhesive and a WSI interposer. Back side wafer-scale power delivery with an isotropic conductive adhesive and a WSI interposer can enable wafer-scale integration power delivery with an isotropic conductive adhesive. A wafer-scale integration (WSI) system is accessed. The WSI system includes a plurality of functional chips. The functional chips can include processor chips, accelerator chips, memory chips, and so on. The WSI can include a plurality of through-silicon vias (TSVs). At least one power module is coupled, by one or more

isotropic conductive adhesives (ICAs), to the WSI system. DC power is sent, by the at least one power module, to the plurality of functional chips.

A wafer-scale integration (WSI) system is used for power delivery to a plurality of functional chips. The functional chips are bonded to a front side of a WSI system. As discussed previously, the functional chips can include processors, multiprocessors, AI accelerators, ML accelerators, switching chips, and so on. The power delivery can be accomplished using a power module. The power module can be coupled to the WSI system by one or more isotropic conductive adhesives (ICAs). The sending power to the functional chips is based on the one or more ICAs. Other elements can be bonded, coupled, etc. to the WSI system. The other elements can include controllers, memories, and so on. Communication between and among the functional chips and the other elements is accomplished using through-silicon vias (TSVs) and interconnect manufactured on and within the WSI system. To enable the fabrication of the TSVs and to improve the reliability of the TSVs, the WSI system wafer can be ground, polished, and so on to reduce the thickness of the WSI system. The resulting thin WSI system wafer can be delicate and therefore susceptible to cracking and fracturing. The WSI system wafer can be reinforced or supported using a stiffening isometric grid array (discussed below). The stiffening isometric grid array can provide stiffening to the WSI system wafer to assist with protecting the WSI system wafer from cracks and fractures.

The illustration 500 includes a wafer-scale integration (WSI) system 510, wherein the WSI system includes a plurality of functional chips 520. The functional chips can include processors, multiprocessors, memories, switching chips, and so on. The WSI can comprise an inorganic wafer such as a silicon wafer, a glass wafer, and so on. The WSI can include an organic wafer. In embodiments, the WSI system comprises a monolithic wafer, wherein the plurality of functional chips is manufactured on the monolithic wafer. Other functional chips can be bonded to the WSI. Additional elements can be bonded to or mounted on the WSI, such as processor chips, multiprocessor chips, graphics processor chips, application-specific integrated circuits (ASICs), systems-on-chip (SoCs), memory chips, artificial intelligence (AI) and machine learning (ML) accelerators, and so on. In embodiments, the WSI system comprises a wafer interposer, wherein the plurality of functional chips comprises a plurality of functional chiplets, wherein a front side of the wafer interposer is bonded to the plurality of functional chiplets, and wherein the wafer interposer includes a plurality of through-

silicon vias (TSVs) 512. The TSVs may be included for some implementations of the WSI system and may be omitted for other implementations of the WSI system.

The functional chips, switching chiplets, and other elements, if present, can create prodigious heat during operation. The heat can be result from current provided to the functional chips and other elements such as active current, overcurrent, leakage current, and so on. The heat can result from IR drops associated with interconnect, active devices, leakage currents, etc. within the functional chips and other elements. The functional chips can be manufactured on the monolithic wafer that comprises the WSI system, The functional chips and other elements can be bonded to the WSI system via micro-bumps, controlled collapse chip connections (C4s), and so on. The WSI system may include a plurality of through-silicon vias (TSVs). A TSV can include an electrical connection that completely passes through a wafer such as a silicon wafer or a die. The plurality of TSVs, if present, can be oriented vertically in order to enable connections between the front side of the wafer and the back side of the wafer.

The illustration 500 includes a plurality of isotropic conductive adhesives (ICAs) 530, wherein the plurality of ICAs couple the WSI system to a plurality of power modules 540. In embodiments, the ICA comprises an epoxy-based isotropic conductive adhesive. The power modules can include modular power substrates (MPSs) (discussed below). The ICAs can be activated by heat, pressure, or time; can require no activation; and so on. The ICAs can be based on a variety of bonding and conduction technologies. In embodiments, the ICA comprises micro-silver flakes. The micro-silver flakes are conductive. In embodiments, the ICA comprises polymer spheres. The polymer spheres can conform to a TSV, to a contact, and the like. In embodiments, the ICA is applied with a stencil printing process. The stencil can direct the ICA to desired contacts, interconnect, TSVs, etc. In further embodiments, the ICA is applied with a ball drop process. A stencil can be used to direct the deposition of ICA micro-balls. In other embodiments, the ICA is applied with an ink jet deposition process. The ICA can be printed onto the WSI system.

The illustration 500 includes an isometric grid array (IGA) 550. The back side of the WSI system can be inserted into the IGA. The IGA, if present, can stiffen the WSI system to stabilize the WSI, planarize the WSI, protect the WSI from fracture and cracking, etc. A cold plate (not shown) can then be attached to the IGA, thus pressing the cold plate to the functional chips on a front side of an interposer such as the interposer comprising the WSI

system 510. The attaching can be accomplished using one or more screws, clips, locking fasteners, and so on, thus stiffening the WSI system. The IGA can provide support for the WSI by enhancing stability of the WSI, stiffness of the WSI, etc. Enhancing the stiffness of the WSI can significantly reduce the risk of the WSI cracking, even under its own weight. The IGA can comprise a grid.

In the illustration 500, the plurality of power modules may comprise a plurality of modular power substrates (MPSs) 540. The plurality of MPSs can be attached to a back side of the WSI by the plurality of ICAs 530. Embodiments further include coupling, using one or more ICAs, to a back side of the wafer interposer, a plurality of modular power substrates (MPSs), wherein each ICA in the one or more ICAs enables each MPS in the plurality of MPSs to be further coupled, based on a TSV in the plurality of TSVs, to one or more functional chiplets within the plurality of functional chiplets. Described previously and throughout, the MPSs can include one or more DC-to-DC converters, a high-power socket, a high voltage socket, etc. such as 560, one or more rigid-flex strips, and so on. Each MPS within the plurality of MPSs can be based on a form factor mirroring one or more corresponding functional chips such as functional chip 520. The functional chips, if present, can be bonded to a front side of the WSI. The one or more MPSs can be attached to the back side of the WSI through the plurality of open recesses in the IGA. Each open recess within the IGA can match a form factor of a corresponding MPS in the plurality of MPSs.

The illustration 500 includes a unified circuit board (UCB) 570. The MPSs discussed above can be mechanically connected to the UCB. Embodiments include connecting mechanically the plurality of MPSs to a unified control board (UCB), wherein the UCB includes a plurality of DC-to-DC power converters 580. An MPS can include a connector, where the connector can be used to mechanically connect the MPS to the UCB. The connector can comprise a socket on the UCB. The socket can comprise a high-power socket, a high voltage socket, etc. The mechanical connection can accommodate a maximum lateral displacement of the UCB due to thermal expansion during operation. In addition to the power connector, the MPS can include a plurality of rigid-flex strips (not shown). The rigid-flex strips can provide a mechanical connection between the MPS and a UCB. A plurality of rigid-flex strips can provide control signals, data, and so on. In embodiments, the mechanical connection can include a

plurality of rigid-flex strips. The plurality of rigid-flex strips can include one or more power control signals from a digital controller chip to the plurality of MPSs.

In the illustration 500, an apparatus for power delivery is disclosed comprising: a wafer-scale integration (WSI) system, wherein the WSI system includes a plurality of functional chips; a plurality of isotropic conductive adhesives (ICAs), wherein the plurality of ICAs couple the WSI system to a plurality of power modules; and one or more voltage converters, wherein the voltage converters perform at least one voltage conversion and send DC power to the plurality of functional chips.

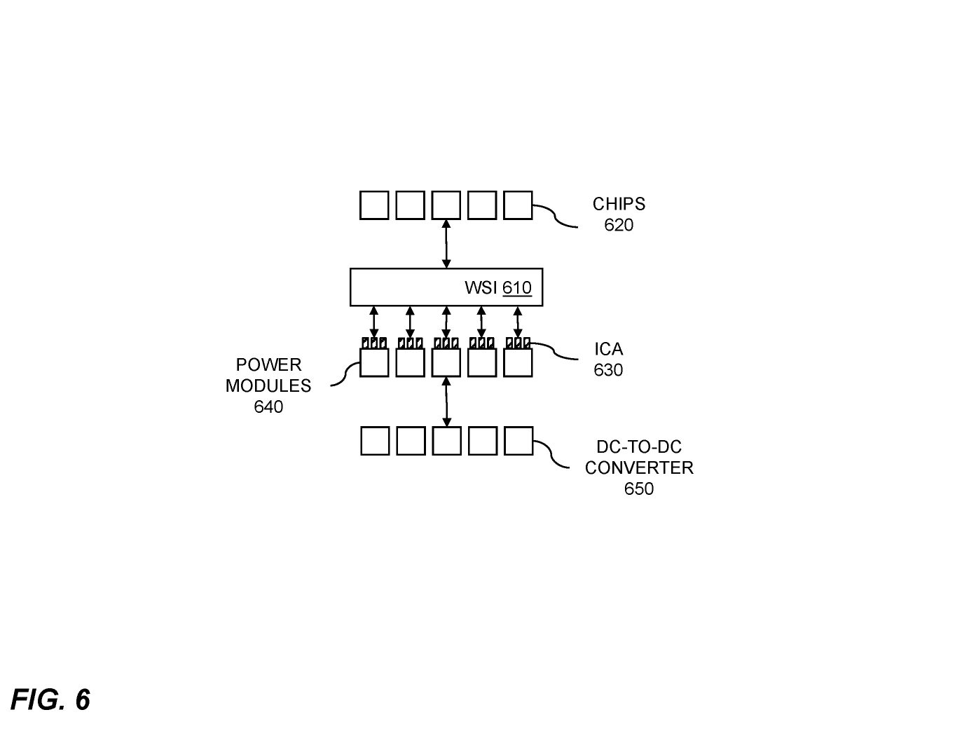

FIG. 6 is an infographic for wafer-scale integration power delivery with an isotropic conductive adhesive (ICA). The isotropic conductive adhesive enables the coupling of at least one power module to a wafer-scale integration (WSI) system. The coupling enables electrical communications between power modules and functional chips without a solder reflow process. Recall that the WSI can be bonded to a plurality of functional chips. The functional chips can include processors, multiprocessors, machine learning (ML) processors, artificial intelligence (AI) accelerators, graphics processors, memories, switching chips such as switching chiplets, and so on. The functional chips can be bonded to a front side of the WSI. The functional chips can be in communication with elements such as modular power substrates (MPSs) that can be attached to a back side of the WSI. The communication between the functional chips and the MPSs can be accomplished using through-silicon vias (TSVs). To enable the fabrication of the TSVs and to improve the reliability of the TSVs, the WSI can be ground, polished, and so on to reduce the thickness of the WSI. The resulting thin WSI can be delicate and therefore susceptible to cracking and fracturing. The modular power substrates are attached based on ICAs to the back side of the WSI. The attaching couples the MPS to one or more functional chips bonded to the front side of the WSI. Stiffening of the WSI can be provided by an isometric grid array (IGA). The IGA can provide stiffening to the WSI to assist with protecting the WSI from cracks and fractures.

A wafer-scale integration (WSI) system is accessed. The WSI system includes a plurality of functional chips. The functional chips can include processor chips, accelerator chips, memory chips, and so on. The WSI can include a plurality of through-silicon vias (TSVs). At least one power module is coupled, by one or more isotropic conductive adhesives (ICAs), to the WSI system. DC power is sent, by the at least one power module, to the

plurality of functional chips. A system for power delivery is disclosed comprising: a wafer-scale integration (WSI) system, wherein the WSI system includes a plurality of functional chips; a plurality of isotropic conductive adhesives (ICAs), wherein the plurality of ICAs couple the WSI system to a plurality of power modules; and one or more voltage converters, wherein the system, when provided DC power, is configured to send DC power to the plurality of functional chips, wherein the sending includes one or more voltage conversions.

The infographic 600 includes a wafer-scale integration (WSI) system 610, wherein the WSI system includes a plurality of functional chips 620. The plurality of functional chips, such as processor chips, switching chips, and so on, can be bonded to a front side of the WSI system. The WSI system can further include a plurality of through-silicon vias (TSVs). The WSI system can comprise an inorganic wafer such as a silicon wafer, a glass wafer, and so on. The WSI system can include an organic wafer. The plurality of functional chips 620 can include general-purpose chips such as processor chips, multiprocessor chips, graphics processor chips, application-specific integrated circuits (ASICs), systems-on-chip (SoCs), memory chips, artificial intelligence (AI) accelerators and machine learning (ML) accelerators, switching chips such as switching chiplets, and so on. The functional chips can be bonded to the WSI system via micro-bumps, controlled collapse chip connections (C4s), and so on. The WSI system can include a plurality of through-silicon vias (TSVs). A TSV can include an electrical connection that completely passes through a wafer such as a silicon wafer or a die. The plurality of TSVs is oriented vertically in order to enable connections between the front side of the wafer and the back side of the wafer.

The infographic 600 includes a plurality of isotropic conductive adhesives (ICAs), wherein the plurality of ICAs couple the WSI system to a plurality of power modules. The ICAs 630 can include a variety of bonding and conducting techniques. In embodiments, the ICA comprises micro-silver flakes. The micro-silver flakes can be suspended in an adhesive such as an epoxy, cyanoacrylate, and so on. In embodiments, the ICA comprises an epoxy-based isotropic conductive adhesive. In embodiments, the ICA comprises polymer spheres. The polymer spheres can conform to irregular surfaces. The polymer spheres can be used to accomplish bonding instead of using an adhesive film. The isotropic conductive adhesives can be applied using a variety of techniques. In embodiments, the ICA is applied with a stencil printing process. The ICA can be applied to the wafer through a stencil. In embodiments, the

ICA is applied with a ball drop process. The ball drop process drops balls of the ICA onto a surface. The ICA balls can be dropped through a stencil. In embodiments, the ICA is applied with an ink jet deposition process. The ink jet process can print the ICA onto the WSI system.

The infographic 600 includes a plurality of power modules 640. The power modules can include modular power substrates (MPSs). The plurality of power modules, such as MPSs, is attached to a back side of the WSI system by the plurality of isotropic conductive adhesives.

The infographic 600 includes one or more voltage converters. The one or more voltage converters can comprise one or more DC-to-DC converters 650. The power modules can include the one or more DC-to-DC converters, a high voltage socket, one or more rigid-flex strips, and so on. The DC-to-DC converters can convert a high DC voltage to a low DC voltage. In embodiments, each power module within the plurality of power modules is based on a form factor mirroring one or more corresponding functional chips, within the plurality of functional chips, on the front side of the WSI system. The one or more power modules can be attached to the back side of the WSI system through an isometric grid array (IGA). Openings in the IGA bypass each power module to contact the WSI system. The IGA accomplishes stiffening of the WSI system.

The converters can be included on a unified circuit board (UCB), not shown. The UCB can be mechanically connected to the plurality of power modules. The UCB can include a plurality of DC-to-DC converters 650. The UCB can be connected mechanically to the plurality of power modules. The connection can be accomplished using a variety of connection techniques, where the connection techniques can be accomplished using locking connectors, non-locking connectors, and so on. The connectors can include rigid connectors, flexible connectors, and the like. The mechanical connection can be based on a high-power socket (which can be a high voltage socket), one or more rigid-flex strips, and so on. The modularity of the MPSs can allow for movement between the UCB and the WSI. Movement, such as a linear displacement, can occur due to differences in coefficients of thermal expansion (CTE). The USB can include one or more control circuits. The control circuits can be used to generate control signals to one or more functional chips, enable transfers of data, control DC-to-DC converters, and the like. The UCB can include a plurality of DC-to-DC power converters (not shown). The DC-to-DC converters can convert DC power from a high DC voltage range, such as 48 volts to

54 volts, to a lower DC voltage range, such as 12 volts to 13.5 volts. The DC-to-DC converters can be mounted on a unified control board (UCB). The UCB can provide controls such as control signals, and power such as DC power, to the DC-to-DC converters. The UCB can comprise a single control board. The single control board can include an organic control board or an inorganic control board. The UCB can comprise multiple control boards and/or circuits. The UCB can include a printed circuit board (PCB). The PCB can include a ceramic PCB, an aluminum nitride PCB, and the like. Aluminum nitride can have a similar CTE to silicon, reducing the lateral displacement between the WSI system and the UCB during operation.

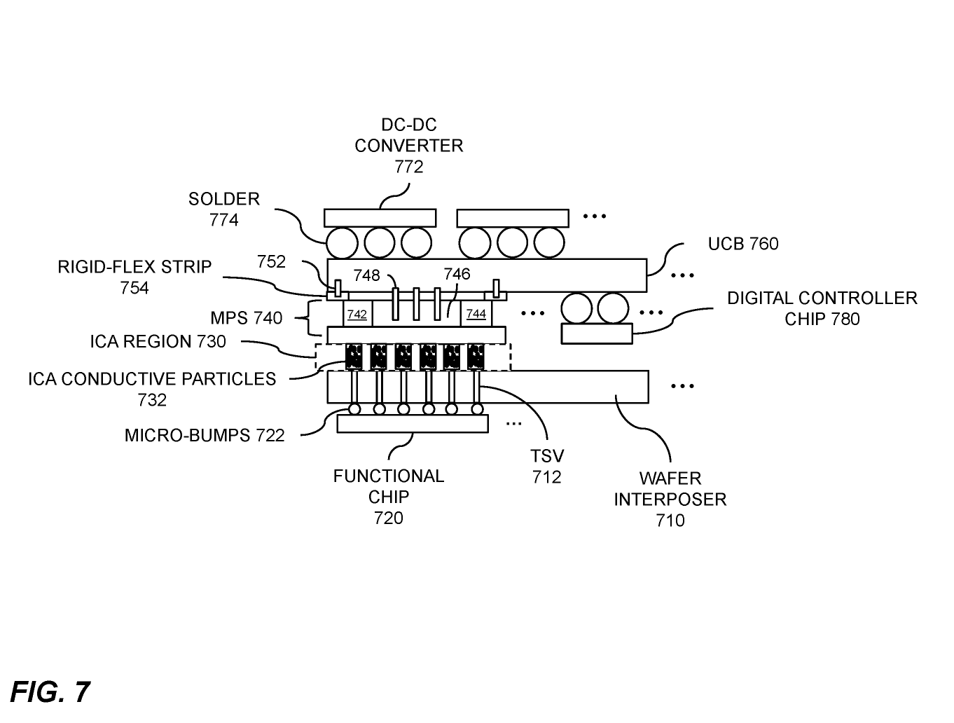

FIG. 7 is an infographic for back side wafer-scale power delivery using a wafer interposer. Back side wafer-scale power delivery using a wafer interposer can enable wafer-scale integration power delivery with an isotropic conductive adhesive. A wafer-scale integration (WSI) system is accessed. The WSI system includes a plurality of functional chips. The functional chips can include processor chips, accelerator chips, memory chips, and so on. The WSI can include a plurality of through-silicon vias (TSVs). At least one power module is coupled, by one or more isotropic conductive adhesives (ICAs), to the WSI system. DC power is sent, by the at least one power module, to the plurality of functional chips.

The infographic 700 includes a wafer interposer 710. The wafer interposer can include organic materials or inorganic materials. The wafer interposer can comprise a 300 mm wafer, a 200 mm wafer, or some other size wafer. The wafer interposer can comprise a wafer-scale integration (WSI) system. A front side of the wafer interposer can be bonded to a plurality of functional chips, such as functional chip 720. The front side of the wafer interposer can be arbitrarily designated as the wafer side to which functional chips are coupled. The functional chips can include a processor chip, multi-core processor chip, system-on-a-chip, a memory chip, an application-specific integrated circuit (ASIC), an artificial intelligence accelerator, and so on. The bonding can include flip-chip mounting the chips to the wafer interposer. Various techniques can be used to make connections to the top of a functional chip. In a usage example, a technique based on micro-bumps 722 can be used. The wafer interposer includes a plurality of through-silicon vias (TSVs) 712. A back side of the wafer interposer can include a plurality of C4s, contacts, landing pads, etc. to couple the wafer interposer to other elements using isotropic conductive adhesives (ICAs), shown as ICA pillars within ICA region 730. The ICAs can be comprised of ICA conductive particles 732 contained within an adhesive

material. The TSVs can provide a connection between the micro-bumps and the C4s. These connections can be used to deliver power to the functional chips through the back side of the wafer interposer. The wafer interposer is associated with a first coefficient of thermal expansion.

The infographic 700 includes a plurality of modular power substrates (MPSs) 740. The plurality of MPSs is coupled to a back side of the wafer interposer. Connections between the wafer interposer and the MPSs can be accomplished using the ICAs described above.The MPSs can include a plurality of step-down power modules and/or DC-to-DC converters such as those shown at 742 and 744. The DC-to-DC converters on the MPSs can accomplish altering of a DC voltage. The MPSs can provide a second voltage conversion. The second voltage conversion can include a second DC-to-DC voltage conversion. The second voltage conversion can result in a voltage which is appropriate for the functionality of the functional chips. The MPS can also provide a voltage for the functional chips appropriate for I/O circuits which can be different than the voltage required for functional circuits.

The infographic 700 includes a unified control board (UCB) 760. The UCB is connected mechanically to the plurality of MPSs. The UCB can comprise multiple, smaller power/control boards and/or circuits. The connection can be based on a connector 746. The connector can be used to mechanically connect the MPSs to the UCB. The connector can include a socket on the UCB. The mechanical connection can include one or more pins 748 which can be inserted into the socket. The mechanical connection can accommodate a maximum lateral displacement of the UCB due to thermal expansion during operation. The lateral displacement can result from various amounts of thermal expansion of the wafer interposer, the UCB, and/or the MPS during operation. Each component can have a different CTE and thus can expand at different rates. In addition to the power connector, the MPS can include a rigid-flex strip 754. The rigid-flex strip can provide a mechanical connection between the MPS and a UCB. The plurality of rigid-flex strips can provide control signals, data, and so on. The mechanical connection can include a plurality of rigid-flex strips. The plurality of rigid-flex strips can include one or more power control signals from the digital controller chip to the plurality of MPSs. The plurality of rigid-flex strips can include one or more signals such as one or more power control signals. The rigid-flex strips can include a socket into which one or more plugs, pins, etc., such as 752, can be inserted to couple the rigid-flex strip to the UCB. The UCB includes a plurality of DC-to-DC power converters 772. The DC-to-DC power converters can

convert a first DC voltage to a second DC voltage. The DC-to-DC power converters can be coupled to the UCB with solder bumps (774). The DC-to-DC converters can be controlled by a digital controller chip 780. The UCB is associated with a second coefficient of thermal expansion. In embodiments, the first coefficient of thermal expansion is different than the second coefficient of thermal expansion.

Each of the above methods may be executed on one or more processors on one or more computer systems. Embodiments may include various forms of distributed computing, client/server computing, and cloud-based computing. Further, it will be understood that the depicted steps or boxes contained in this disclosure’s flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”— may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for power delivery comprising:
accessing a wafer-scale integration (WSI) system, wherein the WSI system includes a plurality of functional chips;
coupling, using one or more isotropic conductive adhesives (ICAs), to the WSI system, at least one power module; and
sending DC power, by the at least one power module, to the plurality of functional chips, wherein the sending is based on the one or more ICAs, and wherein the sending includes one or more voltage conversions.

2. The method of claim 1 wherein the WSI system comprises a monolithic wafer.

3. The method of claim 2 wherein the plurality of functional chips is manufactured on the monolithic wafer.

4. The method of claim 1 wherein the WSI system comprises a wafer interposer.

5. The method of claim 4 wherein the plurality of functional chips comprises a plurality of functional chiplets.

6. The method of claim 5 wherein a front side of the wafer interposer is bonded to the plurality of functional chiplets.

7. The method of claim 6 wherein the wafer interposer includes a plurality of through-silicon vias (TSVs).

8. The method of claim 7 further comprising coupling, using one or more ICAs, to a back side of the wafer interposer, a plurality of modular power substrates (MPSs).

9. The method of claim 8 wherein each ICA in the one or more ICAs enables each MPS in the plurality of MPSs to be further coupled, based on a TSV in the plurality of TSVs, to one or more functional chiplets within the plurality of functional chiplets.

10. The method of claim 8 further comprising connecting mechanically the plurality of MPSs to a unified control board (UCB).

11. The method of claim 10 wherein the UCB includes a plurality of DC-to-DC power converters.

12. The method of claim 11 wherein the sending includes distributing DC power, by the UCB, to the plurality of functional chiplets.

13. The method of claim 12 wherein the distributing includes a first voltage conversion within the one or more voltage conversions.

14. The method of claim 13 wherein the distributing is based on the plurality of MPSs.

15. The method of claim 14 wherein a second voltage conversion within the one or more voltage conversions is accomplished by the plurality of MPSs.

16. The method of claim 1 wherein the ICA comprises micro-silver flakes.

17. The method of claim 1 wherein the ICA comprises polymer spheres.

18. The method of claim 1 wherein the ICA is applied with a stencil printing process.

19. The method of claim 1 wherein the ICA is applied with a ball drop process.

20. The method of claim 1 wherein the ICA is applied with an ink jet deposition process.

21. The method of claim 1 wherein the ICA comprises an epoxy-based isotropic conductive adhesive.

22. An apparatus for power delivery comprising:
a wafer-scale integration (WSI) system, wherein the WSI system includes a plurality of functional chips;
a plurality of isotropic conductive adhesives (ICAs), wherein the plurality of ICAs couple the WSI system to a plurality of power modules; and
one or more voltage converters, wherein the voltage converters perform at least one voltage conversion and send DC power to the plurality of functional chips.

23. A system for power delivery comprising:
a wafer-scale integration (WSI) system, wherein the WSI system includes a plurality of functional chips;
a plurality of isotropic conductive adhesives (ICAs), wherein the plurality of ICAs couple the WSI system to a plurality of power modules; and
one or more voltage converters, wherein the system, when provided DC power, is configured to:
send DC power to the plurality of functional chips, wherein the sending includes one or more voltage conversions.
